(19) United States
(12) Patent Application Publication
(10) Pub. No.: US 2024/0272589 A1
(43) Pub. Date: Aug. 15, 2024

(54) TIME-TO-DIGITAL CONVERTER CIRCUIT

(71) Applicant: ROHM CO., LTD., Kyoto (JP)

(72) Inventors: Keno SATO, Kyoto (JP); Tamotsu ICHIKAWA, Kyoto (JP); Takashi ISHIDA, Kyoto (JP); Toshiyuki OKAMOTO, Kyoto (JP); Takayuki NAKATANI, Kyoto (JP); Haruo KOBAYASHI, Kyoto (JP)

(21) Appl. No.: 18/429,541

(22) Filed: Feb. 1, 2024

(30) Foreign Application Priority Data
Feb. 9, 2023 (JP) 2023-018732

(51) Int. Cl. G04F 10/00; H03M 1/06

(52) U.S. Cl. CPC G04F 10/005; H03M 1/0604

(57) ABSTRACT

A time-to-digital converter circuit that measures a time difference between a first input signal and a second input signal includes: a jitter superimposition circuit that superimposes a jitter, which changes temporally, on one of the first input signal and the second input signal to generate a first intermediate signal and a second intermediate signal; a time-to-digital converter that measures a time difference between the first intermediate signal and the second intermediate signal each time the jitter changes; and a statistical processor that statistically processes a plurality of time differences measured by the time-to-digital converter in response to a plurality of jitters, and calculates a time difference between the first input signal and the second input signal.

### CROSS-REFERENCE TO RELATED APPLICATION

The present invention claims priority under 35 U.S.C. § 119 to Japanese Patent Application No. 2023-018732, filed on Feb. 9, 2023, the entire contents of which is incorporated herein by reference.

### TECHNICAL FIELD

The present disclosure relates to a time measurement technique.

### BACKGROUND

In a semiconductor integrated circuit, a TDC (Time-to-Digital Converter) circuit is used when it is desired to measure time. As a configuration of the TDC circuit, a flash type TDC, a successive approximation register (SAR) TDC, and the like have been proposed.

### BRIEF DESCRIPTION OF DRAWINGS

The accompanying drawings, which are incorporated in and constitute a part of the specification, illustrate embodiments of the present disclosure.

FIG. 1 is a circuit diagram of a time-to-digital converter circuit according to a first embodiment.

FIG. 2 is a circuit diagram showing a configuration example of a jitter superposition circuit.

FIG. 3 is an operation waveform diagram of the jitter superposition circuit of FIG. 2.

FIG. 4 is a circuit diagram showing a configuration example of a time-to-digital converter.

FIG. 5 is a diagram for explaining an operation of the TDC circuit.

FIG. 6 is a circuit diagram of a TDC circuit according to a second embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### Overview of Embodiments

An overview of some exemplary embodiments of the present disclosure is described. This overview presents, in a simplified form, some concepts of one or more embodiments, as a prologue to the detailed description which will be presented later, and for the purpose of basic understanding of the embodiments, but it is not intended to limit the scope of the invention or the disclosure. This overview is not a comprehensive overview of all possible embodiments, and it is intended to neither identify key elements of all embodiments nor delineate the scope of some or all aspects. For the sake of convenience, “an embodiment” may be used to refer to one embodiment (example or modification) or a plurality of embodiments (examples or modifications) disclosed herein.

A time-to-digital converter circuit according to one embodiment measures a time difference between a first input signal and a second input signal. The time-to-digital converter circuit includes: a jitter superimposition circuit that superimposes a jitter, which changes temporally, on one of the first input signal and the second input signal to generate a first intermediate signal and a second intermediate signal; a time-to-digital converter that measures a time difference between the first intermediate signal and the second intermediate signal each time the jitter changes; and a statistical processor that statistically processes a plurality of time differences measured by the time-to-digital converter in response to a plurality of jitters and calculates a time difference between the first input signal and the second input signal.

With the configuration described above, by measuring the time difference for each jitter while changing the jitter and statistically processing the plurality of time differences obtained as a result of the measurement, the time difference between the first input signal and the second input signal can be measured with a resolution higher than that of the time-to-digital converter.

In one embodiment, the time-to-digital converter may be of a successive approximation type.

In one embodiment, the time-to-digital converter may be of a vernier type.

In one embodiment, the time-to-digital converter may include: a programmable delay circuit having a first input node that receives the first intermediate signal, a second input node that receives the second intermediate signal, a first output node that outputs a first delayed signal obtained by applying a variable delay to the first intermediate signal, and a second output node that outputs a second delayed signal obtained by applying a variable delay to the second intermediate signal; a flip-flop that receives the first delayed signal at an input terminal thereof and receives the second delayed signal at a clock terminal thereof; and a successive approximation processor that controls the programmable delay circuit based on an output of the flip-flop and detects a time difference between the first delayed signal and the second delayed signal.

In one embodiment, the time-to-digital converter may be of a flash type.

In one embodiment, the jitter superimposition circuit may include: a first comparator that compares the first input signal with a first reference voltage; and a second comparator that compares the second input signal with a second reference voltage. The first intermediate signal may correspond to an output of the first comparator, the second intermediate signal may correspond to an output of the second comparator, and one of the first reference voltage and the second reference voltage may be a voltage obtained by superimposing an offset voltage, which changes temporally, on the other of the first reference voltage and the second reference voltage.

In one embodiment, the jitter superimposition circuit may further include: a noise source that generates a noise signal; and a low-pass filter that receives the noise signal. An output signal of the low-pass filter may be the offset voltage.

A time-to-digital converter circuit according to another embodiment measures a time difference between a first input signal and a second input signal. The time-to-digital converter circuit includes: a programmable delay circuit having a first input node that receives the first input signal, a second input node that receives the second input signal, a first output node that outputs a first delayed signal obtained by applying a variable delay to the first input signal, and a second output node that outputs a second delayed signal obtained by applying a variable delay to the second input signal; a jitter superimposition circuit that superimposes a jitter, which changes temporally, on one of the first delayed signal and the second delayed signal to generate a first intermediate signal and a second intermediate signal; a flip-flop that receives the first intermediate signal at an input terminal thereof and receives the second intermediate signal at a clock terminal thereof; a successive approximation processor that controls the programmable delay circuit based on an output of the flip-flop and detects a time difference between the first intermediate signal and the second intermediate signal; and a statistical processor that statistically processes a plurality of time differences detected by the successive approximation processor in response to a plurality of jitters and calculates a time difference between the first input signal and the second input signal.

With the configuration described above, by measuring the time difference for each jitter while changing the jitter and statistically processing the plurality of time differences obtained as a result the measurement, the time difference between the first input signal and the second input signal can be measured with a resolution higher than that of the programmable delay circuit.

In another embodiment, the jitter superimposition circuit may include: a first comparator that compares the first delayed signal with a first reference voltage; and a second comparator that compares the second delayed signal with a second reference voltage. The first intermediate signal may correspond to an output of the first comparator, the second intermediate signal may correspond to an output of the second comparator, and one of the first reference voltage and the second reference voltage may be a voltage obtained by superimposing an offset voltage, which changes temporally, on the other of the first reference voltage and the second reference voltage.

In another embodiment, the jitter superimposition circuit may further include: a noise source that generates a noise signal; and a low-pass filter that receives the noise signal. An output signal of the low-pass filter may be the offset voltage.

### EMBODIMENTS

Preferred embodiments of the present disclosure will be now described with reference to the drawings. Like or equivalent components, members, and processes illustrated in each drawing are given like reference numerals and a repeated description thereof will be appropriately omitted. Further, the embodiments are presented by way of example only and are not intended to limit the present disclosure and invention, and any features or combination thereof described in the embodiments may not necessarily be essential to the present disclosure and invention.

In the present disclosure, “a state where a member A is connected to a member B” includes a case where the member A and the member B are physically and directly connected to each other and also a case where the member A and the member B are indirectly connected to each other via any other member that does not affect an electrical connection state between the members A and B or does not impair functions and effects achieved by combinations of the members A and B.

Similarly, “a state where a member C is installed between a member A and a member B” includes a case where the member A and the member C or the member B and the member C are indirectly connected via any other member that does not affect an electrical connection state between the members A and C or the members B and C or does not impair function and effects achieved by combinations of the members A and C or the members B and C, in addition to a case where the member A and the member C or the member B and the member C are directly connected.

In addition, vertical and horizontal axes of a waveform diagram and a time chart shown in the present disclosure are enlarged or reduced as appropriate for ease of understanding, and each waveform shown is also simplified for ease of understanding.

### First Embodiment

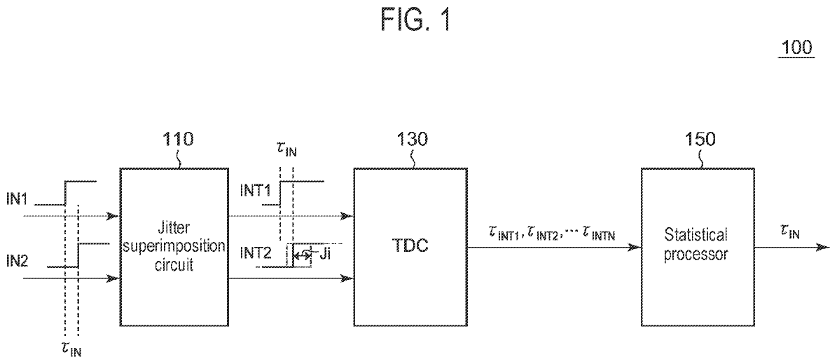

FIG. 1 is a circuit diagram of a time-to-digital converter (TDC) circuit 100 according to a first embodiment. The TDC circuit 100 measures a time difference τ_{IN} between a first input signal IN1 and a second input signal IN2. The time difference τ_{IN} is a time difference between a predetermined edge of the first input signal IN1 and a predetermined edge of the second input signal IN2. In the present embodiment, it is assumed that a time difference between a positive edge of the first input signal IN1 and a positive edge of the second input signal IN2 is measured.

The TDC circuit 100 includes a jitter superposition circuit 110, a time-to-digital converter 130, and a statistical processor 150.

The jitter superimposition circuit 110 superimposes jitters J₁, J₂, J₃, . . . , J_{N} , which change temporally, on one of the first input signal IN1 and the second input signal IN2 to generate a first intermediate signal INT1 and a second intermediate signal INT2. While changing the jitter J, the first input signal IN1 and the second input signal IN2, which have the constant time difference τ_{IN}, are repeatedly input to the TDC circuit 100.

In the present embodiment, the jitter superimposition circuit 110 applies a jitter to the second input signal IN2 to generate the second intermediate signal INT2, and outputs the first input signal IN1, as it is, as the first intermediate signal INT1 without applying a jitter to the first input signal IN1.

The time-to-digital converter 130 measures a time difference τ_{IN} between the first intermediate signal INT1 and the second intermediate signal INT2 each time the jitter J changes. A time difference when the jitter is Jᵢ is expressed as τ_{INTi}.

The statistical processor 150 statistically processes a plurality of time differences to τ_{INTN} measured by the time-to-digital converter 130 in response to the plurality of jitters J₁ to J_{N} , and calculates the time difference τ_{IN} between the first input signal IN1 and the second input signal IN2.

The present disclosure covers various devices and methods that can be understood as the block diagram or circuit diagram of FIG. 1 or derived from the above description, and is not limited to a specific configuration. More specific configuration examples and embodiments will be described below, not to narrow the scope of the present disclosure, but to help understand and clarify the essence and operation of the present disclosure and the present invention.

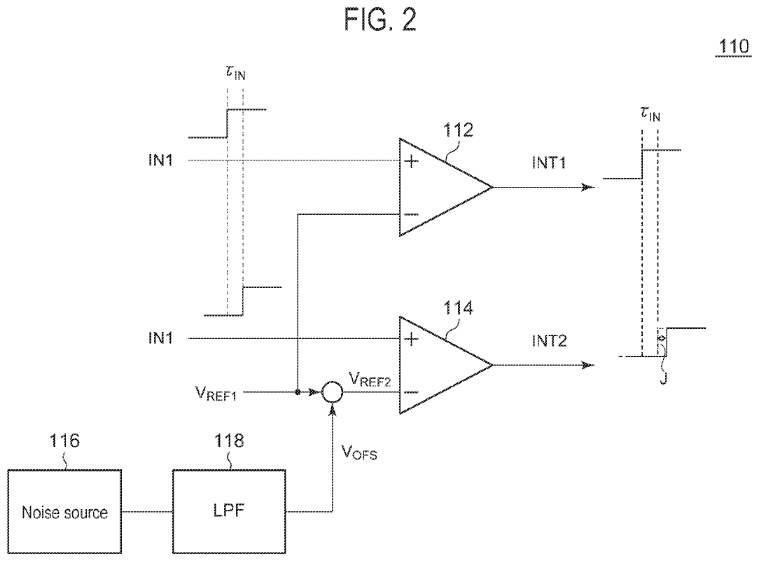

FIG. 2 is a circuit diagram showing a configuration example of the jitter superposition circuit 110. The jitter superposition circuit 110 includes a first comparator 112, a second comparator 114, a noise source 116, and a low-pass filter 118.

The first comparator 112 compares the first input signal IN1 with a first reference voltage V_{REF1}. The second comparator 114 compares the second input signal IN2 with a second reference voltage V_{REF2}. The first intermediate signal INT1 corresponds to an output of the first comparator 112, and the second intermediate signal INT2 corresponds to an output of the second comparator 114.

One of the first reference voltage V_{REF1} and the second reference voltage V_{REF2} is a voltage obtained by superimposing an offset voltage V_{OFS}, which changes temporally, on the other of the first reference voltage V_{REF1} and the second reference voltage V_{REF2}.

The offset voltage V_{OFS} can be generated by the noise source 116 and the low-pass filter 118. The noise source 116 generates a noise signal N. For example, the noise signal N may be a Gaussian noise that follows a normal distribution. The low-pass filter 118 receives the noise signal N, removes high frequency components, and passes only low frequency components. A cutoff frequency of the low-pass filter 118 may be determined so that the offset voltage V_{OFS} can be considered to be at substantially the same level during a period when the time-to-digital converter 130 performs one measurement.

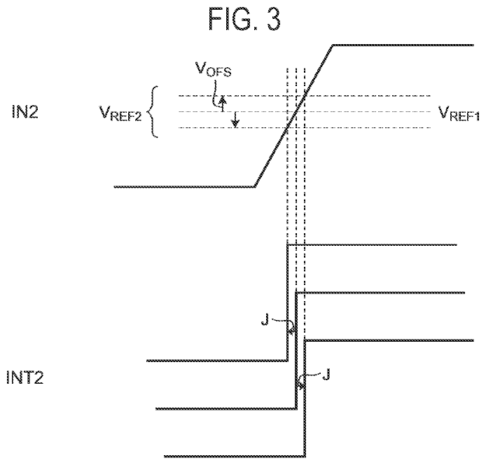

FIG. 3 is an operation waveform diagram of the jitter superposition circuit 110 of FIG. 2. The positive edge of the second input signal IN2 has a certain finite slope. Therefore, the second intermediate signal INT2, which is the output of the second comparator 114, transitions later as the second reference voltage V_{REF2} is higher, and transitions earlier as the second reference voltage V_{REF2} is lower. In other words, the second intermediate signal INT2 is a signal obtained by superimposing the jitter J corresponding to the offset voltage V_{OFS} on the second input signal IN2.

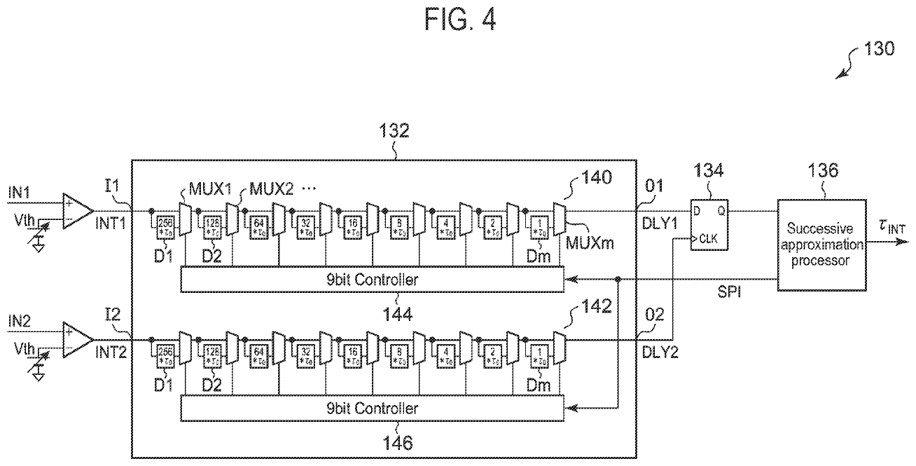

FIG. 4 is a circuit diagram showing a configuration example of the time-to-digital converter 130. The time-to-digital converter 130 is a successive approximation type TDC. The time-to-digital converter 130 includes a programmable delay circuit 132, a flip-flop 134, and a successive approximation processor 136. The programmable delay circuit 132 receives the first intermediate signal INT1 at a first input node I1, applies a controllable delay τ₁ to the first intermediate signal INT1 to generate a first delayed signal DLY1, and outputs the first delayed signal DLY1 from a first output node O1. Similarly, the programmable delay circuit 132 receives the second intermediate signal INT2 at a second input node I2, applies a controllable delay τ₂ to the second intermediate signal INT2 to generate a second delayed signal DLY2, and outputs the second delayed signal DLY2 from a second output node O2. The delay times τ₁ and τ₂ can be controlled according to a control signal from the successive approximation processor 136. The programmable delay circuit 132 may be a commercially available programmable delay circuit. Alternatively, the programmable delay circuit 132 may be integrated on the same IC chip as the flip-flop 134 and the successive approximation processor 136.

For example, the programmable delay circuit 132 includes a first delay line 140, a second delay line 142, a first controller 144, and a second controller 146. The first delay line 140 includes m delay elements D1 to Dm (m≥2,m=9 in this example) that generate binary-weighted delays, and m multiplexers MUX1 to MUXm. A delay element Di of an i-th stage (1≤i≤m) provides a delay to a signal from the previous stage. A delay amount of the delay element Di of the i-th stage is τ₀×2^{(m-i)}, where τ₀ is a delay resolution of the programmable delay circuit 132.

A multiplexer MUXi of an i-th stage (1≤i≤m) receives a signal from a previous stage and an output signal of the delay element Di of the same stage, and outputs one of the signal and the output signal according to a control by the first controller 144 to a subsequent stage.

The second delay line 142 is configured similarly to the first delay line 140.

The D flip-flop (also simply referred to as a flip-flop) 134 receives the first delayed signal DLY1 at an input terminal D thereof, and receives the second delayed signal DLY2 at a clock terminal CLK thereof. An output Q of the flip-flop 134 is input to the successive approximation processor 136.

The output Q of the flip-flop 134 has a high level when an edge of the first delayed signal DLY1 leads an edge of the second delayed signal DLY2. Conversely, when the edge of the first delayed signal DLY1 lags the edge of the second delayed signal DLY2, the output Q of the flip-flop 134 has a low level. In other words, the output Q of the flip-flop 134 represents a sequential relationship between the edge of the first delayed signal DLY1 and the edge of the second delayed signal DLY2 on a time axis.

The successive approximation processor 136 changes a relative delay (τ₁−τ₂) between the first delay line 140 and the second delay line 142, and detects a boundary between the relative delay at which the output of the flip-flop 134 becomes 1 and the relative delay at which the output of the flip-flop 134 becomes 0. The relative delay corresponding to this boundary becomes the time difference τ_{INT} between the first intermediate signal INT1 and the second intermediate signal INT2. The successive approximation processor 136 may control an amount of delay between the first delay line 140 and the second delay line 142 by, for example, processing such as binary search.

After searching a plurality of times, the successive approximation processor 136 outputs a code, which corresponds to the relative delay (τ₁−τ₂) corresponding to the boundary, as data indicating the time difference τ_{INT}. By changing the jitter N times, N time differences τ_{INT1} to τ_{INTN} for N jitters are generated.

The above is the configuration of the TDC circuit 100. Next, an operation of the TDC circuit 100 will be described.

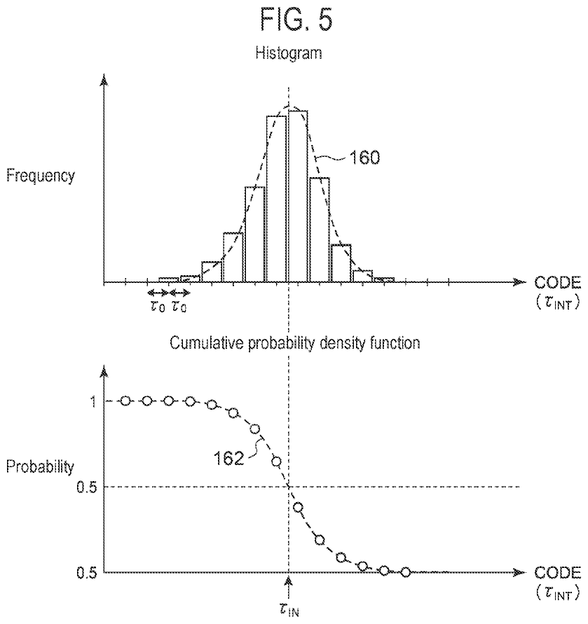

FIG. 5 is a diagram for explaining an operation of the TDC circuit 100. Here, a case in which a jitter J according to a Gaussian distribution is given will be explained.

An upper part of FIG. 5 shows a histogram of the delay amount τ_{INT} measured when the jitter J is changed and measurements are performed N times. The horizontal axis represents a code CODE representing the delay amount τ_{INT}, which takes discrete values with a discrete increment of τ₀. The vertical axis is a frequency of each code CODE.

When the jitter J follows the Gaussian distribution, the histogram also follows the Gaussian distribution. A broken line 160 indicates the Gaussian distribution fit to the histogram. A time difference corresponding to a maximum value of this Gaussian distribution 160 becomes the time difference τ_{IN} between the two input signals IN1 and IN2. This time difference τ_{IN} may be located between two adjacent codes, and has higher accuracy than the time resolution τ₀ of the time-to-digital converter 130.

A broken line 162 at a lower part of FIG. 5 indicates a cumulative probability density function obtained by fitting using the histogram. The delay amount τ_{INT} when the cumulative probability density function 162 has a probability of 0.5 becomes the time difference τ_{IN} between the two input signals IN1 and IN2.

The statistical processor 150 may calculate the time difference τ_{IN} between the two input signals IN1 and IN2 based on the histogram shown in the upper part of FIG. 5. Alternatively, the statistical processor 150 may calculate the time difference τ_{IN} between the two input signals IN1 and IN2 based on the cumulative probability density function shown in the lower part of FIG. 5. In addition, statistical processing for calculating the time difference τ_{IN} is not limited to that described herein and can use various known techniques.

### Second Embodiment

In the first embodiment, a jitter is superimposed at a front stage of the time-to-digital converter 130, but the present disclosure is not limited thereto, and the function of the jitter superposition circuit 110 may be incorporated inside the time-to-digital converter 130.

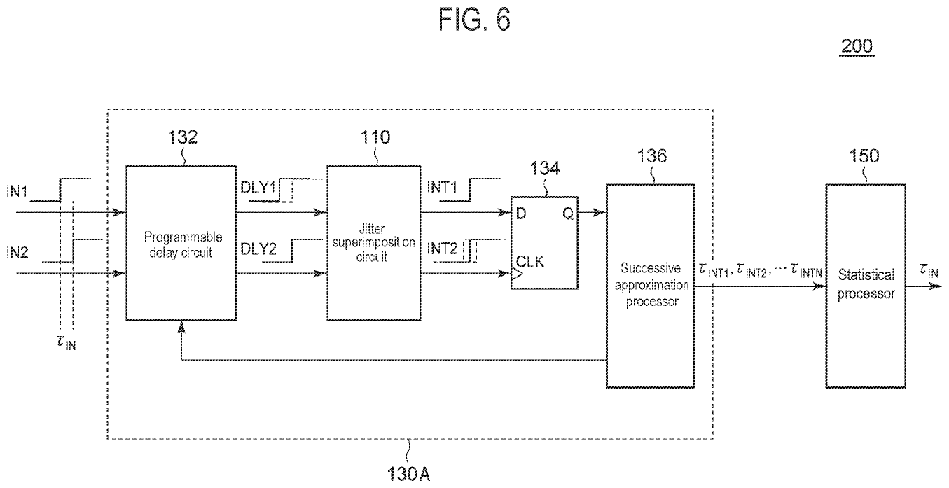

FIG. 6 is a circuit diagram of a TDC circuit 200 according to a second embodiment. The TDC circuit 200 includes a time-to-digital converter 130A and a statistical processor 150. The time-to-digital converter 130A is a circuit in which the jitter superposition circuit 110 is incorporated into the time-to-digital converter 130 in FIG. 1.

The time-to-digital converter 130A includes the programmable delay circuit 132, the jitter superposition circuit 110, the flip-flop 134, and the successive approximation processor 136. The programmable delay circuit 132 changes the relative delay amount between the first input signal IN1 and the second input signal IN2 according to the control from the successive approximation processor 136. The programmable delay circuit 132 outputs the first delayed signal DLY1, which is the first input signal IN1 with the delay τ₁, and a second delayed signal DLY2, which is the second input signal IN2 with the delay τ₂.

The jitter superposition circuit 110 superimposes a jitter on at least one of the first delayed signal DLY1 or the second delayed signal DLY2, and outputs the first intermediate signal INT1 and the second intermediate signal INT2.

The flip-flop 134 receives the first intermediate signal INT1 at the input terminal thereof and receives the second intermediate signal INT2 at the clock terminal thereof. The successive approximation processor 136 changes the relative delay (τ₁−τ₂) of the programmable delay circuit 132 and detects the boundary between the relative delay at which the output of the flip-flop 134 becomes 1 and the relative delay at which the output of the flip-flop 134 becomes 0. The relative delay corresponding to this boundary becomes the time difference τ_{INT} between the first intermediate signal INT1 and the second intermediate signal INT2.

After searching a plurality of times, the successive approximation processor 136 outputs the code, which corresponds to the relative delay (τ₁−τ₂) corresponding to the boundary, as data indicating the time difference τ_{INT}. By changing the jitter N times, N time differences τ_{INT1} to τ_{INTN} for N jitters are generated.

The statistical processor 150 statistically processes the plurality of time differences τ_{INT1} to τ_{INTN} measured by the time-to-digital converter 130 in response to the plurality of jitters J₁ to J_{N}, and calculates the time difference τ_{IN} between the first input signal IN1 and the second input signal IN2.

The jitter superposition circuit 110 and the programmable delay circuit 132 may use those illustrated in the first embodiment.

The above is the configuration of the TDC circuit 200. According to the TDC circuit 200, similarly to the TDC circuit 100 according to the first embodiment, the delay amount τ_{IN} can be measured with a resolution higher than that of the time-to-digital converter 130.

Finally, modifications will be described.

### First Modification

In the embodiments, a successive approximation type time-to-digital converter is used as the time-to-digital converter 130, but the present disclosure is not limited thereto, and a flash-type time-to-digital converter may be used.

### Second Modification

A vernier type delay circuit that can obtain high resolution using the caliper principle may be used as the programmable delay circuit 132 of the time-to-digital converter 130.

### Third Modification

The configuration of the jitter superposition circuit 110 and the method of jitter superposition are not limited to those described in the embodiments.

### Supplementary Notes

The following techniques are disclosed in the present disclosure.

### Supplementary Note 1

A time-to-digital converter circuit that measures a time difference between a first input signal and a second input signal, including:
a jitter superimposition circuit that superimposes a jitter, which changes temporally, on one of the first input signal and the second input signal to generate a first intermediate signal and a second intermediate signal;
a time-to-digital converter that measures a time difference between the first intermediate signal and the second intermediate signal each time the jitter changes; and
a statistical processor that statistically processes a plurality of time differences measured by the time-to-digital converter in response to a plurality of jitters and calculates a time difference between the first input signal and the second input signal.

### Supplementary Note 2

The time-to-digital converter circuit of Supplementary Note 1, wherein the time-to-digital converter is of a successive approximation type.

### Supplementary Note 3

The time-to-digital converter circuit of Supplementary Note 2, wherein the time-to-digital converter is of a vernier type.

### Supplementary Note 4

The time-to-digital converter circuit of Supplementary Note 2 or 3, wherein the time-to-digital converter includes:
a programmable delay circuit having a first input node that receives the first intermediate signal, a second input node that receives the second intermediate signal, a first output node that outputs a first delayed signal obtained by applying a variable delay to the first intermediate signal, and a second output node that outputs a second delayed signal obtained by applying a variable delay to the second intermediate signal;
a flip-flop that receives the first delayed signal at an input terminal of the flip-flop and receives the second delayed signal at a clock terminal of the flip-flop; and
a successive approximation processor that controls the programmable delay circuit based on an output of the flip-flop and detects a time difference between the first delayed signal and the second delayed signal.

### Supplementary Note 5

The time-to-digital converter circuit of Supplementary Note 1, wherein the time-to-digital converter is of a flash type.

### Supplementary Note 6

The time-to-digital converter circuit of any one of Supplementary Notes 1 to 5, wherein the jitter superposition circuit includes:
a first comparator that compares the first input signal with a first reference voltage; and
a second comparator that compares the second input signal with a second reference voltage,
wherein the first intermediate signal corresponds to an output of the first comparator,
wherein the second intermediate signal corresponds to an output of the second comparator, and
wherein one of the first reference voltage and the second reference voltage is a voltage obtained by superimposing an offset voltage, which changes temporally, on the other of the first reference voltage and the second reference voltage.

### Supplementary Note 7

The time-to-digital converter circuit of Supplementary Note 6, wherein the jitter superposition circuit further includes:
a noise source that generates a noise signal; and
a low-pass filter that receives the noise signal,
wherein an output signal of the low-pass filter is the offset voltage.

### Supplementary Note 8

A time-to-digital converter circuit that measures a time difference between a first input signal and a second input signal, including:
a programmable delay circuit having a first input node that receives the first input signal, a second input node that receives the second input signal, a first output node that outputs a first delayed signal obtained by applying a variable delay to the first input signal, and a second output node that outputs a second delayed signal obtained by applying a variable delay to the second input signal;
a jitter superimposition circuit that superimposes a jitter, which changes temporally, on one of the first delayed signal and the second delayed signal to generate a first intermediate signal and a second intermediate signal;
a flip-flop that receives the first intermediate signal at an input terminal of the flip-flop and receives the second intermediate signal at a clock terminal of the flip-flop;
a successive approximation processor that controls the programmable delay circuit based on an output of the flip-flop and detects a time difference between the first intermediate signal and the second intermediate signal; and
a statistical processor that statistically processes a plurality of time differences detected by the successive approximation processor in response to a plurality of jitters and calculates a time difference between the first input signal and the second input signal.

### Supplementary Note 9

The time-to-digital converter circuit of Supplementary Note 8, wherein the jitter superposition circuit includes:
a first comparator that compares the first delayed signal with a first reference voltage; and
a second comparator that compares the second delayed signal with a second reference voltage,
wherein the first intermediate signal corresponds to an output of the first comparator,
wherein the second intermediate signal corresponds to an output of the second comparator, and
wherein one of the first reference voltage and the second reference voltage is a voltage obtained by superimposing an offset voltage, which changes temporally, on the other of the first reference voltage and the second reference voltage.

### Supplementary Note 10

The time-to-digital converter circuit of Supplementary Note 9, wherein the jitter superposition circuit further includes:
a noise source that generates a noise signal; and
a low-pass filter that receives the noise signal,
wherein an output signal of the low-pass filter is the offset voltage.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A time-to-digital converter circuit that measures a time difference between a first input signal and a second input signal, comprising:
a jitter superimposition circuit that superimposes a jitter, which changes temporally, on one of the first input signal and the second input signal to generate a first intermediate signal and a second intermediate signal;
a time-to-digital converter that measures a time difference between the first intermediate signal and the second intermediate signal each time the jitter changes; and
a statistical processor that statistically processes a plurality of time differences measured by the time-to-digital converter in response to a plurality of jitters, and calculates a time difference between the first input signal and the second input signal.

2. The time-to-digital converter circuit of claim 1, wherein the time-to-digital converter is of a successive approximation type.

3. The time-to-digital converter circuit of claim 2, wherein the time-to-digital converter is of a vernier type.

4. The time-to-digital converter circuit of claim 2, wherein the time-to-digital converter includes:
a programmable delay circuit having a first input node that receives the first intermediate signal, a second input node that receives the second intermediate signal, a first output node that outputs a first delayed signal obtained by applying a variable delay to the first intermediate signal, and a second output node that outputs a second delayed signal obtained by applying a variable delay to the second intermediate signal;
a flip-flop that receives the first delayed signal at an input terminal of the flip-flop and receives the second delayed signal at a clock terminal of the flip-flop; and
a successive approximation processor that controls the programmable delay circuit based on an output of the flip-flop and detects a time difference between the first delayed signal and the second delayed signal.

5. The time-to-digital converter circuit of claim 1, wherein the time-to-digital converter is of a flash type.

6. The time-to-digital converter circuit of claim 1, wherein the jitter superposition circuit includes:
a first comparator that compares the first input signal with a first reference voltage; and
a second comparator that compares the second input signal with a second reference voltage,
wherein the first intermediate signal corresponds to an output of the first comparator,
wherein the second intermediate signal corresponds to an output of the second comparator, and
wherein one of the first reference voltage and the second reference voltage is a voltage obtained by superimposing an offset voltage, which changes temporally, on the other of the first reference voltage and the second reference voltage.

7. The time-to-digital converter circuit of claim 6, wherein the jitter superposition circuit further includes:
a noise source that generates a noise signal; and
a low-pass filter that receives the noise signal,
wherein an output signal of the low-pass filter is the offset voltage.

8. A time-to-digital converter circuit that measures a time difference between a first input signal and a second input signal, comprising:
a programmable delay circuit having a first input node that receives the first input signal, a second input node that receives the second input signal, a first output node that outputs a first delayed signal obtained by applying a variable delay to the first input signal, and a second output node that outputs a second delayed signal obtained by applying a variable delay to the second input signal;
a jitter superimposition circuit that superimposes a jitter, which changes temporally, on one of the first delayed signal and the second delayed signal to generate a first intermediate signal and a second intermediate signal;
a flip-flop that receives the first intermediate signal at an input terminal of the flip-flop and receives the second intermediate signal at a clock terminal of the flip-flop;
a successive approximation processor that controls the programmable delay circuit based on an output of the flip-flop and detects a time difference between the first intermediate signal and the second intermediate signal; and
a statistical processor that statistically processes a plurality of time differences detected by the successive approximation processor in response to a plurality of jitters, and calculates a time difference between the first input signal and the second input signal.

9. The time-to-digital converter circuit of claim 8, wherein the jitter superposition circuit includes:
a first comparator that compares the first delayed signal with a first reference voltage; and
a second comparator that compares the second delayed signal with a second reference voltage,
wherein the first intermediate signal corresponds to an output of the first comparator,
wherein the second intermediate signal corresponds to an output of the second comparator, and
wherein one of the first reference voltage and the second reference voltage is a voltage obtained by superimposing an offset voltage, which changes temporally, on the other of the first reference voltage and the second reference voltage.

10. The time-to-digital converter circuit of claim 9, wherein the jitter superposition circuit further includes:
a noise source that generates a noise signal; and
a low-pass filter that receives the noise signal,
wherein an output signal of the low-pass filter is the offset voltage.
